(19) United States
(12) Patent Application Publication
(10) Pub. No.: US 2024/0096831 A1
(43) Pub. Date: Mar. 21, 2024

(54) SEMICONDUCTOR PACKAGE

(71) Applicant: Samsung Electronics Co., Ltd., Suwon-si (KR)

(72) Inventors: Enbin Jo, Suwon-si (KR); Hyungchul Shin, Suwon-si (KR); Wonil Lee, Suwon-si (KR); Hyuekjae Lee, Suwon-si (KR); Gwangjae Jeon, Suwon-si (KR)

(21) Appl. No.: 18/455,943

(22) Filed: Aug. 25, 2023

(30) Foreign Application Priority Data
Sep. 19, 2022 (KR) 10-2022-0117648

(51) Int. Cl. H01L 23/00; H01L 25/065

(52) U.S. Cl. CPC H01L 24/08; H01L 25/0657; H01L 24/16; H01L 2224/0801; H01L 2224/08058; H01L 2224/08146; H01L 2224/16227; H01L 2225/06541; H01L 2924/37

(57) ABSTRACT

A semiconductor package includes: a first semiconductor chip including a first pad on a first substrate, and a first insulating layer at least partially surrounding the first pad; and a second semiconductor chip including a second pad below a second substrate and contacting the first pad, and a second insulating layer at least partially surrounding the second pad and contacting the first insulating layer. The first pad includes a first surface contacting the second pad and a second surface opposite the first surface, and an inclined side surface between the first surface and the second surface. The inclined side surface includes a first side surface and a second side surface, facing each other and inclined at a first obtuse angle and a second obtuse angle with respect to the second surface, respectively. Each of the first and second obtuse angles is about 100° to about 130°.

### CROSS-REFERENCE TO RELATED APPLICATION(S)

This application is based on and claims priority to Korean Patent Application No. 10-2022-0117648, filed on Sep. 19, 2022 in the Korean Intellectual Property Office, the disclosure of which is incorporated herein by reference in its entirety.

### BACKGROUND

Embodiments of the present disclosure relate to a semiconductor package.

As demand for high capacity, thinness, and miniaturization of electronic products increases, various types of semiconductor packages are being developed. Recently, as a method for integrating more components (e.g., semiconductor chips) into a package structure, a direct bonding technology for bonding semiconductor chips without an adhesive film (e.g., a non-conductive film (NCF)) or a connection bump (e.g., a solder ball) has been developed.

### SUMMARY

An aspect of the present disclosure is to provide a semiconductor package having improved reliability.

According to an aspect of the present disclosure, a semiconductor package includes: a first semiconductor chip including a first substrate, a first pad on the first substrate, and a first insulating layer at least partially surrounding the first pad on the first substrate; and a second semiconductor chip on the first semiconductor chip, and including a second substrate, a second pad below the second substrate and contacting the first pad, and a second insulating layer at least partially surrounding the second pad and contacting the first insulating layer, wherein the first pad includes a first surface contacting the second pad and a second surface opposite the first surface, and an inclined side surface between the first surface and the second surface, wherein the inclined side surface includes a first side surface and a second side surface, facing each other and inclined at a first obtuse angle and a second obtuse angle with respect to the second surface, respectively, and wherein each of the first and second obtuse angles is about 100° to about 130°.

According to an aspect of the present disclosure, a semiconductor package includes: a first semiconductor chip including a first substrate, a first pad on the first substrate, and a first insulating layer at least partially surrounding the first pad on the first substrate; and a second semiconductor chip on the first semiconductor chip, and including a second substrate, a second pad below the second substrate and contacting the first pad, and a second insulating layer at least partially surrounding the second pad and contacting the first insulating layer, wherein the first pad includes a first surface contacting the second pad, a second surface opposite the first surface, and a first side surface between the first surface and the second surface and inclined with respect to the second surface at a first obtuse angle, and the second pad includes a third surface contacting the first pad, a fourth surface opposite the third surface, and a second side surface between the third surface and the fourth surface and inclined with respect to the fourth surface at a second obtuse angle, wherein each of the first and second obtuse angles is about 100° to about 130°.

According to an aspect of the present disclosure, a semiconductor package includes: a first semiconductor chip including a first substrate, a first pad on the first substrate, a first insulating layer at least partially surrounding the first pad on the first substrate, an insulating protective layer between the first substrate and the first insulating layer, a through-electrode extending through the first substrate and the insulating protective layer and connected to the first pad, and a buffer film on the insulating protective layer and spaced apart from the through-electrode; and a second semiconductor chip on the first semiconductor chip, and including a second substrate, a second pad below the second substrate and contacting the first pad, and a second insulating layer at least partially surrounding the second pad and contacting the first insulating layer, wherein the first pad includes a first surface contacting the second pad and a second surface opposite the first surface; and an inclined side surface between the first surface and the second surface, wherein the first pad has a first side surface and an opposite second side surface inclined at a first obtuse angle and a second obtuse angle with respect to the second surface, respectively, and wherein each of the first and second obtuse angles is about 100° to about 130°.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a cross-sectional view illustrating a semiconductor package according to an embodiment.

FIG. 1B is a partially enlarged view illustrating portion ‘A’ of FIG. 1A.

FIG. 2 is a partially enlarged view illustrating a modified example of a semiconductor package according to an embodiment.

FIG. 3 is a partially enlarged view illustrating a modified example of a semiconductor package according to an embodiment.

FIG. 4 is a partially enlarged view illustrating a modified example of a semiconductor package according to an embodiment.

FIG. 5 is a cross-sectional view illustrating a semiconductor package according to an embodiment.

FIG. 6A is a plan view illustrating a semiconductor package according to an embodiment.

FIG. 6B is a cross-sectional view of FIG. 6A, taken along line I-I′.

FIG. 7A is a plan view illustrating a semiconductor package according to an embodiment.

FIG. 7B is a cross-sectional view of FIG. 7A, taken along line II-IF.

FIG. 8 is a flowchart illustrating a method of manufacturing a semiconductor package according to an embodiment according to a process sequence.

FIG. 9 illustrates a bonding process between a first structure and a second structure, to illustrate a method of manufacturing a semiconductor package according to an embodiment.

FIGS. 10A to 10G are cross-sectional views illustrating a manufacturing process for forming a first pad on a rear surface of a semiconductor chip.

FIGS. 11A to 11C are cross-sectional views illustrating a manufacturing process for forming a second pad on a front surface of a semiconductor chip.

FIG. 12 is a cross-sectional view illustrating a manufacturing process of the semiconductor package of FIG. 1A.

### DETAILED DESCRIPTION

Hereinafter, example embodiments will be described with reference to the accompanying drawings.

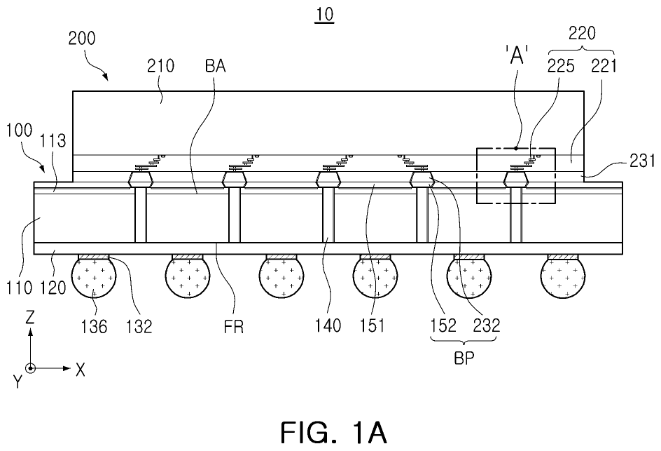

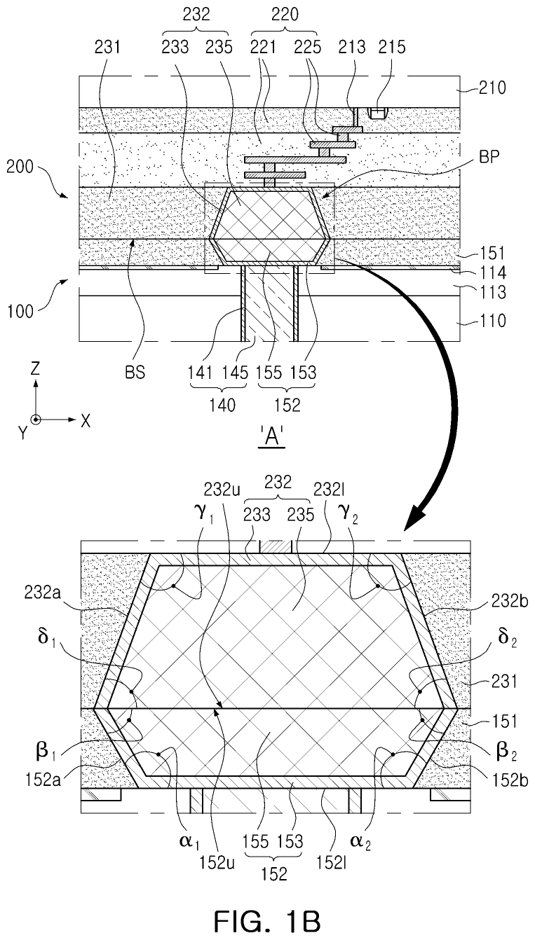

FIG. 1A is a cross-sectional view illustrating a semiconductor package according to an embodiment, and FIG. 1B is a partially enlarged view illustrating portion ‘A’ of FIG. 1A.

Referring to FIG. 1A, a semiconductor package 10 according to an embodiment may include a plurality of semiconductor chips, for example, a first semiconductor chip 100 and a second semiconductor chip 200, stacked in a vertical direction (a Z-axis direction). In the first semiconductor chip 100 and the second semiconductor chip 200, an upper surface of the first semiconductor chip 100 and a lower surface of the second semiconductor chip 200 may be directly joined and bonded (which, for example, may be referred to as hybrid bonding, direct bonding, or the like) without a connection member such as a metal bump or the like. A first insulating layer 151 and first upper pads 152, which provide the upper surface of the first semiconductor chip 100, may be joined and bonded to a second insulating layer 231 and second lower pads 232, which provide the lower surface of the second semiconductor chip 200, respectively. The first semiconductor chip 100 may be electrically connected to the second semiconductor chip 200 by bonding pad structures BP in which the first upper pads 152 and the second lower pads 232 are joined.

The present disclosure may prevent occurrence of defects of the first upper pads 152 and the second lower pads 232, in a process of forming the first upper pads 152 and the second lower pads 232, by adjusting angles formed between a first surface 152u and first and second side surfaces 152a and 152b in each of the first upper pads 152, and/or angles formed between a fourth surface 2321 and third and four side surfaces 232a and 232b in each of the second lower pads 232. Through this, a semiconductor package 10 with improved reliability may be provided.

For example, at least a portion of the first insulating layer 151 may be located on a side surface of the first upper pad 152, and at least a portion of the second insulating layer 231 may be located on a side surface of the second lower pad 232. In this case, the at least portion of the first insulating layer 151 may be in contact with the at least portion of the second insulating layer 231. Therefore, the side surface of the first upper pad 152 and the side surface of the second lower pad 232 may be entirely covered or surrounded with the first and second insulating layers 151 and 231. In this case, to distinguish positions of components in the first semiconductor chip 100 or the second semiconductor chip 200, the “first insulating layer” and the “second insulating layer” may be referred to as a “first upper insulating layer” or “first rear insulating layer,” and a “second lower insulating layer” or “second front insulating layer,” respectively. Also, the “first upper pad” and the “second lower pad” may be referred to as a “first pad” or “first rear pad,” and a “second pad” or “second front pad,” respectively.

Hereinafter, components in the first semiconductor chip 100 and the second semiconductor chip 200 will be described in detail with reference to FIG. 1B together with FIG. 1A.

The first semiconductor chip 100 may include a first substrate 110, a first circuit layer 120, a first through-electrode 140, a first insulating layer 151, and a first upper pad 152. The first semiconductor chip 100 may have a flat upper surface provided by an upper surface of the first insulating layer 151 and an upper surface of the first upper pads 152. For example, the upper surface of the first insulating layer 151 and the upper surface of the first upper pads 152 exposed from the first insulating layer 151 may be substantially coplanar.

The first substrate 110 may be a semiconductor wafer substrate having a front surface FR and a rear surface BA, opposing each other. For example, the first substrate 110 may be a semiconductor wafer including a semiconductor element such as silicon or germanium, or a compound semiconductor such as silicon carbide (SiC), gallium arsenide (GaAs), indium arsenide (InAs), or indium phosphide (InP). The front surface FR may be an active surface having an active region doped with impurities, and the rear surface BA may be an inactive surface opposite to the front surface FR. An insulating protective layer 113 electrically insulating the first upper pad 152 and the first substrate 110 may be disposed on the rear surface BA of the first substrate 110. For example, the insulating protective layer 113 may include silicon oxide (SiO), silicon nitride (SiN), silicon carbide (SiC), silicon oxynitride (SiON), or silicon carbonitride (SiCN). A buffer film 114 such as a polishing stop layer or a barrier may be disposed on an upper surface of the insulating protective layer 113. For example, the buffer film 114 may include silicon nitride, silicon carbide, silicon oxynitride, or silicon carbonitride.

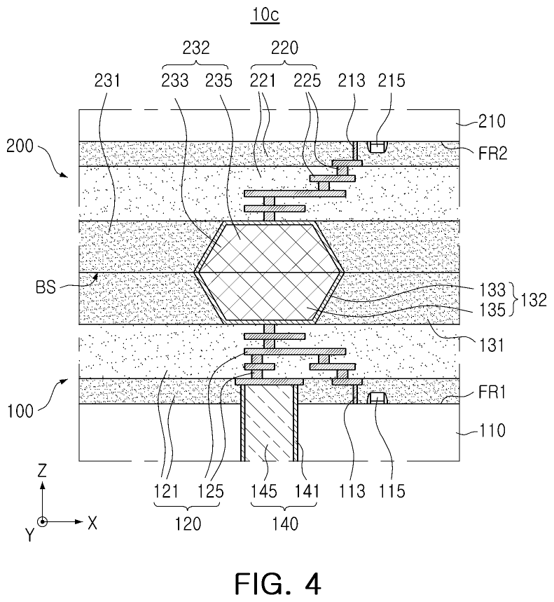

The first circuit layer 120 may be disposed on the front surface FR of the first substrate 110, and may include a first interconnection structure connected to the active region, and a first interlayer insulating layer surrounding the first interconnection structure. A first lower pad 132 electrically connected to an interconnection structure may be disposed below the first circuit layer 120. The first lower pad 132 may be a pad structure electrically connected to an interconnection structure. A connection bump 136 may be disposed below the first lower pad 132. The connection bump 136 may be a conductive bump structure including, for example, a solder ball, a copper (Cu) post, or the like. The first circuit layer 120 may have the same or a structure similar to that of a second circuit layer 220 illustrated in FIG. 1B. Therefore, the first interconnection structure and the first interlayer insulating layer can be understood as having characteristics similar to those of a second interconnection structure 225 and a second interlayer insulating layer 221 in the second circuit layer 220, to be described below. In addition, referring to the modified example of FIG. 4, structures of a first interconnection structure (125′ in FIG. 4) and a first interlayer insulating layer (121′ in FIG. 4) in the first circuit layer 120 can be easily understood.

The first through-electrode 140 may pass or extend through the first substrate 110 and the insulating protective layer 113, to electrically connect the first upper pad 152 and the first lower pad 132. The first through-electrode 140 may include a via plug 145 and a side barrier layer 141 surrounding a side surface of the via plug 145. The via plug 145 may include, for example, tungsten (W), titanium (Ti), aluminum (Al), or copper (Cu), and may be formed by a plating process, a PVD process, or a CVD process. The side barrier layer 141 may include titanium (Ti), titanium nitride (TiN), tantalum (Ta), or tantalum nitride (TaN), and may be formed by a plating process, a PVD process, or a CVD process. A side insulating layer including an insulating material (e.g., a high aspect ratio process (HARP) oxide) such as silicon oxide, silicon nitride, silicon oxynitride, or the like may be formed between the side barrier layer 141 and the first substrate 110.

The first insulating layer 151 may be disposed on the rear surface BA of the first substrate 110. The first insulating layer 151 may include an insulating material that may be joined and bonded to the second insulating layer 231 below the second semiconductor chip 200. For example, the first insulating layer 151 may include silicon oxide (SiO) or silicon carbonitride (SiCN). For example, at least a portion of the first insulating layer 151 may be joined to the second insulating layer 231, to form a bonding surface BS for joining and bonding the first semiconductor chip 100 and the second semiconductor chip 200.

The first upper pad 152 may be disposed on the rear surface BA of the first substrate 110, and may include a first barrier layer 153 and a first conductive layer 155. At least a portion of the first upper pad 152 may be joined to the second lower pad 232 of the second semiconductor chip 200, to physically and electrically connect the first semiconductor chip 100 and the second semiconductor chip 200. A bonding pad structure BP and a bonding surface BS may be formed. The first barrier layer 153 may conformally extend between the first conductive layer 155 and the first insulating layer 151, and may be formed to surround a periphery of the first conductive layer 155. The first conductive layer 155 and the first barrier layer 153 may include a conductive material. For example, the first conductive layer 155 may include at least one of copper (Cu), nickel (Ni), gold (Au), or silver (Ag), and the first barrier layer 153 may include titanium (Ti), titanium nitride (TiN), tantalum (Ta), or tantalum nitride (TaN).

As illustrated in FIG. 1B, in a cross-section perpendicular to the upper surface of the first substrate 110, the first upper pad 152 may include a second surface 1521 of the first upper pad 152 disposed below the first upper pad 152, and side surfaces 152a and 152b inclined at first and second obtuse angles α1 and α2 with respect to the second surface 1521 of the first upper pad 152, respectively. The side surfaces 152a and 152b may include a first side surface 152a inclined at a first obtuse angle αl with respect to the second surface 1521 of the first upper pad 152, and a second side surface 152b inclined at a second obtuse angle α2 with respect to the second surface 1521 of the first upper pad 152. The first side surface 152a and the second side surface 152b may face each other or be opposite each other. Each of the first and second obtuse angles α1 and α2 may have magnitudes in a range of about 100° to about 130° or 100° to 130°. The first upper pad 152 may include a first surface 152u of the first upper pad 152 disposed on the first upper pad 152, and a second surface 1521 of the first upper pad 152 facing or opposite the first surface 152u of the first upper pad 152 in a vertical direction (z), perpendicular to the upper surface of the first substrate 110. In a cross-section perpendicular to the upper surface of the first substrate 110, the first upper pad 152 may have side surfaces 152a and 152b inclined at first and second acute angles (31 and (32 with respect to the first surface 152u of the first upper pad 152, respectively. Each of the first and second acute angles (31 and (32 may have magnitudes in a range of about 50° to about 80° or 50° to 80°. The first upper pad 152 may have a trapezoidal shape in which a horizontal width of the first surface 152u of the first upper pad 152 in a first direction (x) is wider than a horizontal width of the second surface 1521 of the first upper pad 152 in the first direction (x).

When each of the angles between the second surface 1521 and the first and second side surfaces 152a and 152b in each of the first upper pads 152 and/or each of the angles between the fourth surface 2321 and the third and fourth side surfaces 232a and 232b in each of the second lower pads 232 is less than about 100°, in a process of forming the first upper pad 152 and the second lower pad 232, ion concentration may occur in a portion in which the second surface 1521 of the first upper pad 152 meets the first and second side surfaces 152a and 152b, causing fine cracks to occur. In order to solve the above problems, according to the present disclosure, each of the angles between the second surface 1521 and the first and second side surfaces 152a and 152b in each of the first upper pads 152 and/or each of the angles between the fourth surface 2321 and the third and fourth side surfaces 232a and 232b in each of the second lower pads 232 may be set to be about 100° or more.

When each of the angles between the second surface 1521 and the first and second side surfaces 152a and 152b in each of the first upper pads 152 and/or each of the angles between the fourth surface 2321 and the third and fourth side surfaces 232a and 232b in each of the second lower pads 232 exceeds about 130°, a center portion may be concave in a process of forming the first upper pad 152 and the second lower pad 232. Therefore, in the process of bonding the first upper pad 152 and the second lower pad 232, a void may occur between the first surface 152u of the first upper pad 152 and the third surface 232u of the second lower pad 232. Therefore, according to the present disclosure, each of the angles between the second surface 1521 and the first and second side surfaces 152a and 152b in each of the first upper pads 152 and/or each of the angles between the fourth surface 2321 and the third and fourth side surfaces 232a and 232b in each of the second lower pads 232 may be set to be about 130° or less.

According to an embodiment, magnitudes of the first and second obtuse angles α1 and α2 may be different from each other, but are not limited thereto.

The second semiconductor chip 200 may be disposed on the first semiconductor chip 100, and may include a second substrate 210, a second circuit layer 220, a second insulating layer 231, and a second lower pad 232. The second semiconductor chip 200 may have a flat lower surface provided by a lower surface of the second insulating layer 231 and a lower surface of the second lower pad 232. For example, the lower surface of the second insulating layer 231 and the lower surface of the second lower pads 232 exposed from the second insulating layer 231 may be substantially coplanar. Since the first semiconductor chip 100 and the second semiconductor chip 200 may have substantially the same or similar structures, the same or similar components may be denoted by the same or similar reference numerals, and hereinafter, the same components may be repeated. For example, it can be understood that the second substrate 210 has substantially the same characteristics as the first substrate 110 described above.

The second circuit layer 220 may be disposed on a front surface or an active surface of the second substrate 210, and may include a second interconnection structure 225 connected to an active region and a second interlayer insulating layer 221 surrounding the second interconnection structure 225.

The second interlayer insulating layer 221 may be or include a flowable oxide (FOX), a tonen silazen (TOSZ), an undoped silica glass (USG), a borosilica glass (BSG), a phosphosilaca glass (PSG), a borophosphosilica glass (BPSG), a plasma enhanced tetra ethyl ortho silicate (PETEOS), a fluoride silicate glass (FSG), a high density plasma (HDP) oxide, a plasma enhanced oxide (PEOX), a flowable CVD (FCVD) oxide, or a combination thereof. At least a portion of the second interlayer insulating layer 221 surrounding the second interconnection structure 225 may be formed of a low dielectric layer. The second interlayer insulating layer 221 may be formed using a chemical vapor deposition (CVD) process, a flowable-CVD process, or a spin coating process.

The second interconnection structure 225 may be formed, for example, as a multilayer structure including an interconnection pattern and a via, formed of aluminum (Al), gold (Au), cobalt (Co), copper (Cu), nickel (Ni), lead (Pb), tantalum (Ta), tellurium (Te), titanium (Ti), tungsten (W), or a combination thereof. A barrier film including titanium (Ti), titanium nitride (TiN), tantalum (Ta), or tantalum nitride (TaN) may be disposed between the interconnection pattern or/and via and the second interlayer insulating layer 221. Individual components 215 constituting an integrated circuit may be disposed on the front surface of the second substrate 210. In this case, the second interconnection structure 225 may be electrically connected to the individual components 215 through an interconnection portion 213 (e.g., a contact plug). The individual components 215 may include an FET such as a planar FET, a FinFET, or the like, a flash memory, a memory element such as a DRAM, an SRAM, an EEPROM, a PRAM, an MRAM, an FeRAM, an RRAM, or the like, a logic element such as AND, OR, NOT, or the like, various active and/or passive elements such as a system LSI, a CIS, and an MEMS.

The second insulating layer 231 may be disposed below the second substrate 210 or the second circuit layer 220. The second insulating layer 231 may include an insulating material that may be joined and bonded to the first insulating layer 151 of the first semiconductor chip 100. For example, the second insulating layer 231 may include silicon oxide (SiO) or silicon carbonitride (SiCN). For example, at least a portion of the second insulating layer 231 may be joined to the first insulating layer 151, to form a bonding surface BS for joining and bonding the first semiconductor chip 100 and the second semiconductor chip 200. In addition, the second insulating layer 231 may be formed to surround a plurality of second lower pads 232 arranged on a lower surface thereof. In this case, the second insulating layer 231 may be referred to as a second lower insulating layer 231.

The second lower pad 232 may be disposed below the second substrate 210, and may include a second barrier layer 233 and a second conductive layer 235. At least a portion of the second lower pad 232 may be joined to the first upper pad 152 of the first semiconductor chip 100, to physically and electrically connect the first semiconductor chip 100 and the second semiconductor chip 200. A bonding pad structure BP and a bonding surface BS may be formed. The second barrier layer 233 and the second conductive layer 235 may be formed of the same or similar structures and materials as the first barrier layer 153 and the first conductive layer 155 described above.

As illustrated in FIG. 1B, the first upper pad 152 may include a first surface 152u contacting the second lower pad 232, a second surface 1521 opposite to the first surface 152u, and inclined side surfaces 152a and 152b located between the first surface 152u and the second surface 1521. The second lower pad 232 may include a third surface 232u contacting the first upper pad 152, a fourth surface 2321 opposite to the third surface 232u, and inclined side surfaces 232a and 232b located between the third surface 232u and the fourth surface 2321. In a cross-section perpendicular to the upper surface of the first substrate 110, the second lower pad 232 may include a third side surface 232a inclined at a third obtuse angle γ1 with respect to the fourth surface 2321, and a fourth side surface 232b inclined at a fourth obtuse angle γ2 with respect to the fourth surface 2321. The third side surface 232a and the fourth side surface 232b may face each other or be opposite each other. Each of the third obtuse angle γ1 and the fourth obtuse angle γ2 may have magnitudes in a range of about 100° to about 130° or 100° to 130°.

The second lower pad 232 may include a fourth surface 2321 in which the second lower pad 232 and the second insulating layer 231 are in contact with each other, and a third surface 232u facing or opposite the fourth surface 2321 in a vertical direction (z), perpendicular to the upper surface of the first substrate 110, and may have third and fourth side surfaces 232a and 232b inclined at third and fourth acute angles M and 62 with respect to the third surface 232u, respectively. Each of the third and fourth acute angles M and 62 may have magnitudes in a range of about 50° to about 80° or 50° to 80°.

According to an embodiment, magnitudes of the third and fourth obtuse angles γ1 and γ2 may be different from each other, but are not limited thereto.

According to an embodiment, magnitudes of the first and second obtuse angles α1 and α2 may be different from magnitudes of the third and fourth obtuse angles γ1 and γ2, but are not limited thereto.

According to an embodiment, a thickness of the first upper pad 152 in the vertical direction (z), perpendicular to the upper surface of the first substrate 110 may be less or thinner than a thickness of the second lower pad 232 in the vertical direction (z), but is not limited thereto.

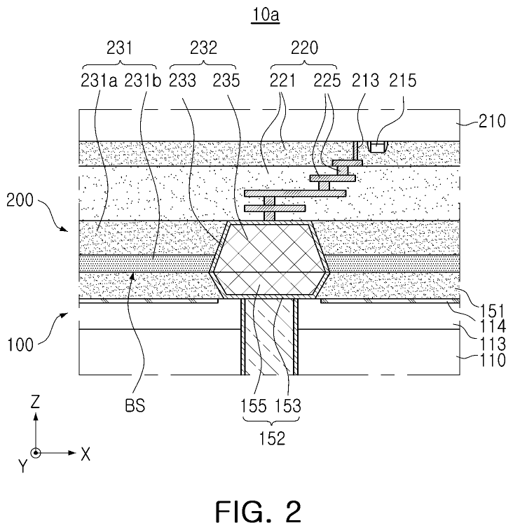

FIG. 2 is a partially enlarged view illustrating a modified example of a semiconductor package according to an embodiment.

Referring to FIG. 2, a semiconductor package 10a of a modified example may have a heterojunction structure in which different materials are joined on a joining interface between a first upper insulating layer 151 and a second lower insulating layer 231. For example, the second lower insulating layer 231 may include a lower insulating film 231b directly contacting the first upper insulating layer 151, and an upper insulating film 231a disposed on the lower insulating film 231b. To improve adhesion between the first upper insulating layer 151 and the second lower insulating layer 231, the lower insulating film 231b may include an insulating material, different from an insulating material of the first upper insulating layer 151. For example, the first upper insulating layer 151 may include silicon oxide (SiO), and the lower insulating film 231b of the second lower insulating layer 231 may include silicon carbonitride (SiCN).

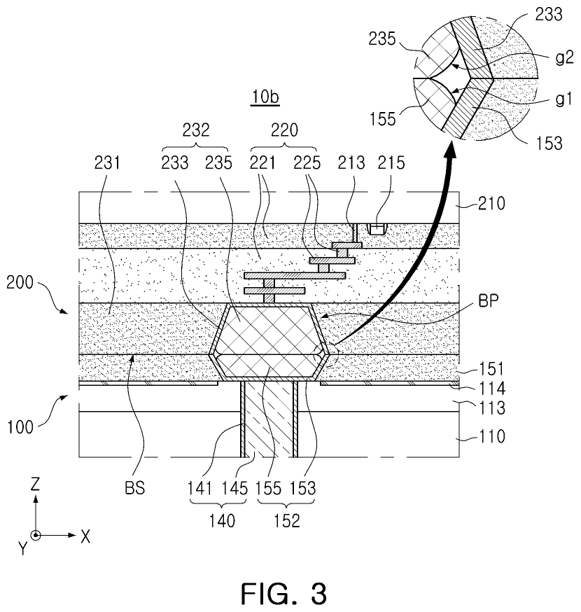

FIG. 3 is a partially enlarged view illustrating a modified example of a semiconductor package according to an embodiment.

Referring to FIG. 3, a semiconductor package 10b of a modified example may include grooves g1 and g2 formed in a bonding pad structure BP. For example, a first upper pad 152 may include a first conductive layer 155 and a first barrier layer 153 surrounding a side surface of the first conductive layer 155, and a second lower pad 232 may include a second conductive layer 235 contacting at least a portion of the first conductive layer 155, and a second barrier layer 233 surrounding a side surface of the second conductive layer 235, the first conductive layer 155 may have a first groove g1 exposing at least a portion of the first barrier layer 153, and the second conductive layer 235 may have a second groove g2 exposing at least a portion of the second barrier layer 233. For example, at least a portion of an inner wall of the first barrier layer 153 and at least a portion of an inner wall of the second barrier layer 233 may be exposed or spaced apart from the first conductive layer 155 and the second conductive layer 235 by the first groove g1 and the second groove g2, respectively. An outer wall of the first barrier layer 153 and an outer wall of the second barrier layer 233 may be covered by a first upper insulating layer 151 and a second lower insulating layer 231, respectively. The first groove g1 and the second groove g2 may be more stably bonded to the first upper pad 152 and the second lower pad 232, fixed by a bonding surface BS by securing an expansion space of the first conductive layer 155 and an expansion space of the second conductive layer 235 during joining and bonding processes of the first upper pad 152 and the second lower pad 232, respectively.

FIG. 4 is a partially enlarged view illustrating a modified example of a semiconductor package according to an embodiment.

Referring to FIG. 4, in a semiconductor package 10c of a modified example, a second semiconductor chip 200 may be stacked on a first circuit layer 120 of a first semiconductor chip 100. For example, the first semiconductor chip 100 and the second semiconductor chip 200 may be arranged such that a first front surface FR1 (e.g., of a first substrate 110) and a second front surface FR2 (e.g., of a second substrate 210) face each other. A first circuit layer 120, a first front insulating layer 131, and a first front pad 132 may be arranged on the first front surface FR1 of the first semiconductor chip 100, and a second circuit layer 220, a second front insulating layer 231, and a second front pad 232 may be arranged on the second front surface FR2 of the second semiconductor chip 200. A thickness of the first front pad 132 in the vertical direction (z), perpendicular to an upper surface of a first substrate 110, may be substantially equal to a thickness of the second front pad 232 in the vertical direction (z). Also, the first front pad 132 and the second front pad 232 may be symmetrical with respect to a bonding surface BS on which the first front pad 132 and the second front pad 232 are in contact with each other. The first circuit layer 120 may include a first interconnection structure 125 electrically connected to individual components 115 through an interconnection portion, and a first interlayer insulating layer 121 surrounding the first interconnection structure 125. Since the first circuit layer 120 has substantially the same characteristics as the above-described second circuit layer 220, overlapping descriptions will be omitted in the interest of brevity. A first insulating layer 151 (or a first upper insulating film or layer) and a first upper pad 152 may be disposed on opposite sides of a first front insulating layer 131 and a first front pad 132, respectively. In addition, it can be understood that the second front insulating layer 231 and the second front pad 232 are the same as the above-described second lower insulating layer 231 and the above-described second lower pad 232, respectively. For example, the present modified example may have the same or similar characteristics to those described with reference to FIGS. 1A to 3, except that the first semiconductor chip 100 of FIG. 1A is vertically inverted and joined to the second semiconductor chip 200.

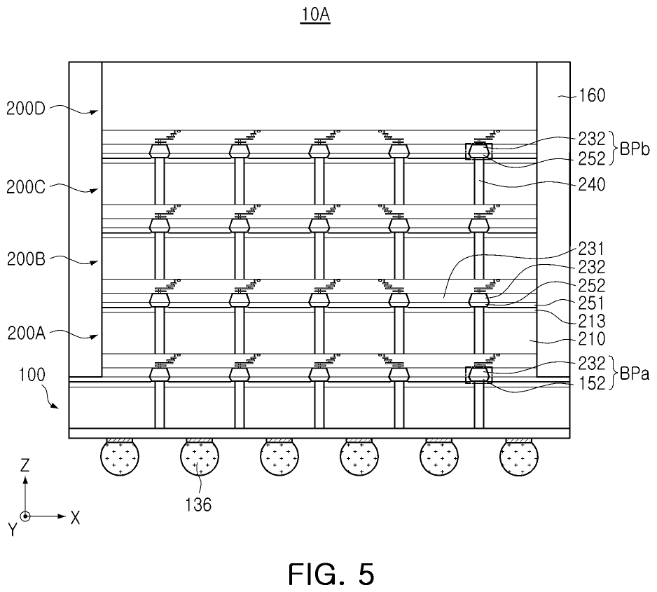

FIG. 5 is a cross-sectional view illustrating a semiconductor package 10A according to an embodiment.

Referring to FIG. 5, since a semiconductor package 10A according to an embodiment has the same or similar features to those described with reference to FIGS. 1A to 4, except that the semiconductor package 10A includes a plurality of second semiconductor chips 200A, 200B, 200C, and 200D stacked in the vertical direction (the Z-axis direction) on a first semiconductor chip 100 and a molding member 160, duplicate descriptions may be omitted in the interest of brevity.

Between the plurality of second semiconductor chips 200A, 200B, 200C, and 200D, a joining interface on which a second rear insulating layer 251 and a second front insulating layer 231 are joined, and a joining interface on which a second rear pad 252 and a second front pad 232 are joined may be formed. The plurality of second semiconductor chips 200A, 200B, 200C, and 200D may be electrically connected to each other by an upper bonding pad structure BPb in which a second rear pad 252 and a second front pad 232 are joined and bonded. Among the plurality of second semiconductor chips 200A, 200B, 200C, and 200D, a lowermost second semiconductor chip 200A may be electrically connected to the first semiconductor chip 100 by a lower bonding pad structure BPa in which a second front pad 232 is joined and bonded to a first rear pad 152 of the first semiconductor chip 100.

The second plurality of semiconductor chips 200A, 200B, 200C, and 200D may include the same or similar features to those described with reference to FIGS. 1A to 4, except for further including a second through-electrode 240 for forming mutual electrical connection paths. It may have the same or similar structure as the semiconductor chip 200. An uppermost second semiconductor chip 200D may not include the second through-electrode 240, and may have a relatively large thickness. According to an embodiment, more or fewer semiconductor chips than illustrated in the drawings may be stacked on the first semiconductor chip 100. For example, three or less or five or more semiconductor chips may be stacked on the first semiconductor chip 100.

For example, the first semiconductor chip 100 may be a buffer chip or a control chip including a plurality of logic devices and/or a plurality of memory devices. The first semiconductor chip 100 may transmit a signal from the plurality of second semiconductor chips 200A, 200B, 200C, and 200D, stacked thereon, to the outside, and may also transmit a signal and power from the outside to the plurality of second semiconductor chips 200A, 200B, 200C, and 200D. The plurality of second semiconductor chips 200A, 200B, 200C, and 200D may be memory chips including volatile memory devices such as a DRAM or an SRAM or non-volatile memory devices such as a PRAM, an MRAM, an FeRAM, and an RRAM. In this case, the semiconductor package 10A of the present embodiment may be used as a high bandwidth memory (HBM) product, an electro data processing (EDP) product, or the like.

The molding member 160 may be disposed on the first semiconductor chip 100, and may seal at least a portion of each of the plurality of second semiconductor chips 200A, 200B, 200C, and 200D. The molding member 160 may be formed to expose an upper surface of the uppermost second semiconductor chip 200D. According to embodiments, the molding member 160 may be formed to cover the upper surface of the uppermost second semiconductor chip 200D. The molding member 160 may include, for example, an epoxy mold compound (EMC), but a material of the molding member 160 is not particularly limited.

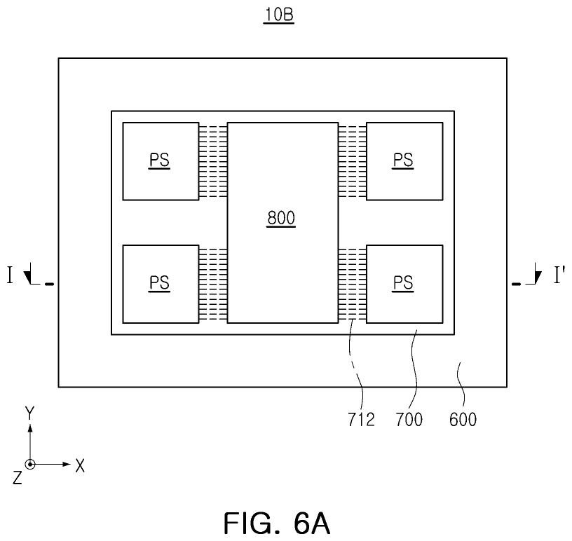

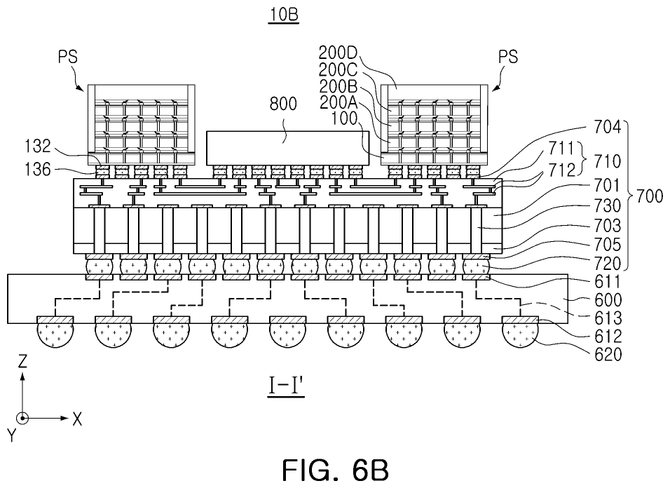

FIG. 6A is a plan view illustrating a semiconductor package 10B according to an embodiment, and FIG. 6B is a cross-sectional view of FIG. 6A, taken along line I-I′.

Referring to FIGS. 6A and 6B, a semiconductor package 10B according to an embodiment may include a package substrate 600, an interposer substrate 700, and at least one package structure PS. In addition, the semiconductor package 10B may further include a logic chip (or a processor chip) 800 disposed adjacent to the package structure PS on the interposer substrate 700. Although the package structure PS is illustrated to form the semiconductor package 10A illustrated in FIG. 5, but is not limited thereto, and may have the same or similar characteristics as the semiconductor packages 10, 10a, 10b, and 10c, described with reference to FIGS. 1A to 4.

The package substrate 600 may be a support substrate on which the interposer substrate 700, the logic chip 800, and the package structure PS are mounted, and may be a substrate for a semiconductor package including a printed circuit board (PCB), a ceramic substrate, a glass substrate, a tape wiring board, and the like. The package substrate 600 may include a lower pad 612 disposed at or on a lower surface of a body, an upper pad 611 disposed at or on an upper surface of the body, and an interconnection circuit 613 electrically connecting the lower pad 612 and the upper pad 611. The body of the package substrate 600 may include a material, depending on a type of substrate. For example, when the package substrate 600 is a printed circuit board, the package substrate 600 may have a configuration in which an interconnection layer is additionally stacked on one surface or both surfaces of a body copper-clad laminate or a copper-clad laminate. The lower and upper pads 612 and 611 and the interconnection circuit 613 may form an electrical path connecting lower and upper surfaces of the package substrate 600. An external connection bump 620 connected to the lower pad 612 may be disposed on the lower surface of the package substrate 600. The external connection bump 620 may include, for example, a solder ball.

The interposer substrate 700 may include a substrate 701, a lower protective layer 703, a lower pad 705, an interconnection structure 710, a conductive bump 720, and a through-via 730. The package structure PS and the processor chip 800 may be stacked on the package substrate 600 via the interposer substrate 700. The interposer substrate 700 may electrically connect the package structure PS and the processor chip 800 to each other.

The substrate 701 may be formed as, for example, any one of a silicon substrate, an organic substrate, a plastic substrate, and a glass substrate. When the substrate 701 is a silicon substrate, the interposer substrate 700 may be referred to as a silicon interposer. When the substrate 701 is an organic substrate, the interposer substrate 700 may be referred to as a panel interposer.

The lower protective layer 703 may be disposed on a lower surface of the substrate 701, and the lower pad 705 may be disposed on the lower protective layer 703. The lower pad 705 may be connected to the through-via 730. The package structure PS and the processor chip 800 may be electrically connected to the package substrate 600 through conductive bumps 720 disposed on the lower pad 705.

The interconnect structure 710 may be disposed on an upper surface of the substrate 701, and may include an interlayer insulating layer 711 and a single layer interconnection structure or multilayer interconnection structure 712. When the interconnection structure 710 has a multilayer interconnection structure, interconnection patterns of different layers may be connected to each other through a contact via. An upper pad 704 connected to the interconnection structure 712 may be disposed on the interconnection structure 710. The package structure PS and the processor chip 800 may be connected to the upper pad 704 through a connection bump 136.

The through-via 730 may extend from the upper surface of the substrate 701 to the lower surface of the substrate 701 to pass through the substrate 701. For example, the through-via 730 may extend into the interconnection structure 710, to be electrically connected to interconnections of the interconnection structure 710. When the substrate 701 is silicon, the through-via 730 may be referred to as a through-silicon via (TSV). Depending on embodiments, the interposer substrate 700 may include only the interconnection structure therein, and may not include the through-via.

The interposer substrate 700 may be used for the purpose of converting or transmitting an input electrical signal between the package substrate 600 and the package structure PS or the processor chip 800. Therefore, the interposer substrate 700 may not include elements such as active elements or passive elements. Depending on an embodiment, the interconnection structure 710 may be disposed below the substrate 701.

The conductive bump 720 may be disposed on a lower surface of the interposer substrate 700, and electrically connected to interconnections of the interconnection structure 710. The interposer substrate 700 may be mounted on the package substrate 600 through the conductive bump 720. For example, some of a plurality of the lower pad 705 used for power or ground may be integrated and connected to the conductive bump 720, such that the number of lower pads 705 may be larger than the number of conductive bumps 720.

The processor chip 800 (or logic chip) may include, for example, a central processing unit (CPU), a graphics processing unit (GPU), a field programmable gate array (FPGA), a digital signal processor (DSP), a cryptographic processor, a microprocessor, a microcontroller, an analog-to-digital converter, an application specific integrated circuit (ASIC), or the like. Depending on types of integrated circuits included in the processor chip 800, the semiconductor package 10B may be referred to as a server-side semiconductor package, a mobile-side semiconductor package, or the like. Depending on embodiments, the number of processor chips 800 and/or package structures PS mounted on the interposer substrate 700 may be more or less than those illustrated in the drawings.

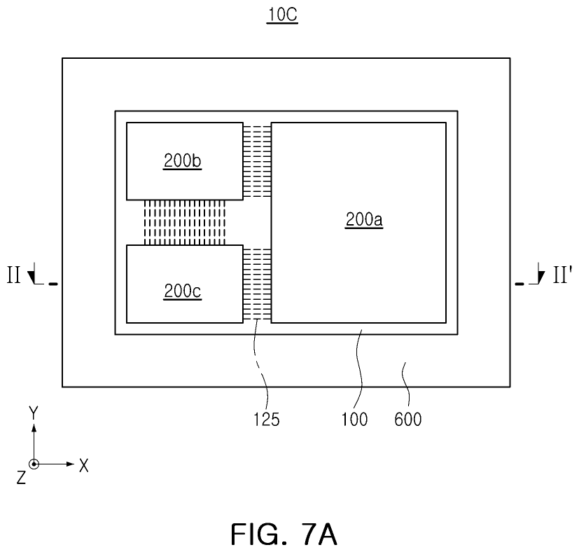

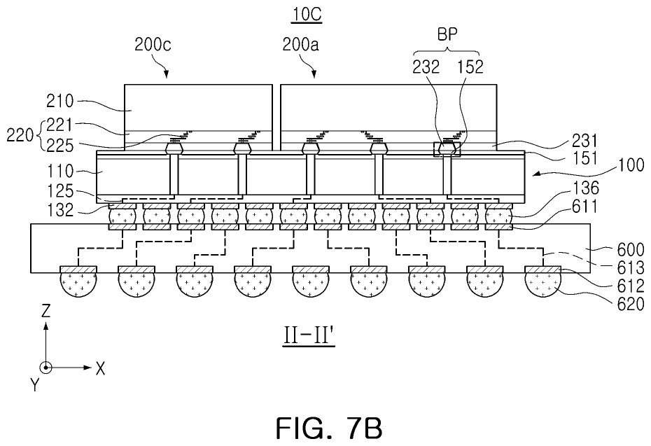

FIG. 7A is a plan view illustrating a semiconductor package 10C according to an embodiment, and FIG. 7B is a cross-sectional view of FIG. 7A, taken along line II-II′.

Referring to FIGS. 7A and 7B, a semiconductor package 10C according to an embodiment may include a plurality of second semiconductor chips 200a, 200b, and 200c, horizontally arranged on a first semiconductor chip 100. In the present embodiment, the plurality of second semiconductor chips 200a, 200b, and 200c (also referred to as ‘chiplets’) may include chiplets constituting a multi-chip module (MCM). For example, the second semiconductor chips 200a, 200b, and 200c may be mounted on the first semiconductor chip 100. According to embodiments, the second semiconductor chips 200a, 200b, and 200c may be electrically connected to each other through a first interconnection structure 125 of the first semiconductor chip 100. A bonding pad structure BP, as described with reference to FIGS. 1A to 4, may be formed between the first semiconductor chip 100 and the second semiconductor chips 200a, 200b, and 200c. A first upper pad 152 and a second lower pad 232 of the bonding pad structure BP may include first and second side surfaces 152a and 152b respectively inclined at first and second obtuse angles α1 and α2 with respect to a second surface 1521 of the first upper pad 152, and third and fourth side surfaces 232a and 232b respectively inclined at third and fourth obtuse angles γ1 and γ2 with respect to a fourth surface 2321, respectively (see FIG. 1B). Therefore, defects of the first upper pad 152 and the second lower pad 232 may be minimized.

The first semiconductor chip 100 may include an active interposer functioning as an I/O chip. For example, the first semiconductor chip 100 may include an I/O device, a DC/DC converter, a sensor, a test circuit, or the like therein. Since the first semiconductor chip 100 may include elements similar to those of the interposer substrate 700 illustrated in FIG. 6B, duplicate descriptions will be omitted in the interest of brevity. In the drawings, although the first semiconductor chip 100 is illustrated as forming a silicon interposer substrate, a substrate applicable to the present embodiment is not limited thereto. The first semiconductor chip 100 may be mounted on the package substrate 600.

The second semiconductor chips 200a, 200b, and 200c may include a CPU, a GPU, an FPGA, or the like. The second semiconductor chips 200a, 200b, and 200c may be composed of different chips. For example, a first chiplet 200a may be a GPU chip, a second chiplet 200b may be a CPU chip, and a third chiplet 200c may be an FPGA chip. According to embodiments, the second semiconductor chips 200a, 200b, and 200c may be composed of the same type of chips. For example, all of the second semiconductor chips 200a, 200b, and 200c may include GPU chips. The number of chiplets disposed on the first semiconductor chip 100 is not particularly limited, and for example, two or less or four or more chiplets may be mounted on the first semiconductor chip 100. In this case, the chiplet or the chiplet technology may refer to a semiconductor chip manufactured separately according to a size and a function of a device, or a technology for manufacturing such a semiconductor chip.

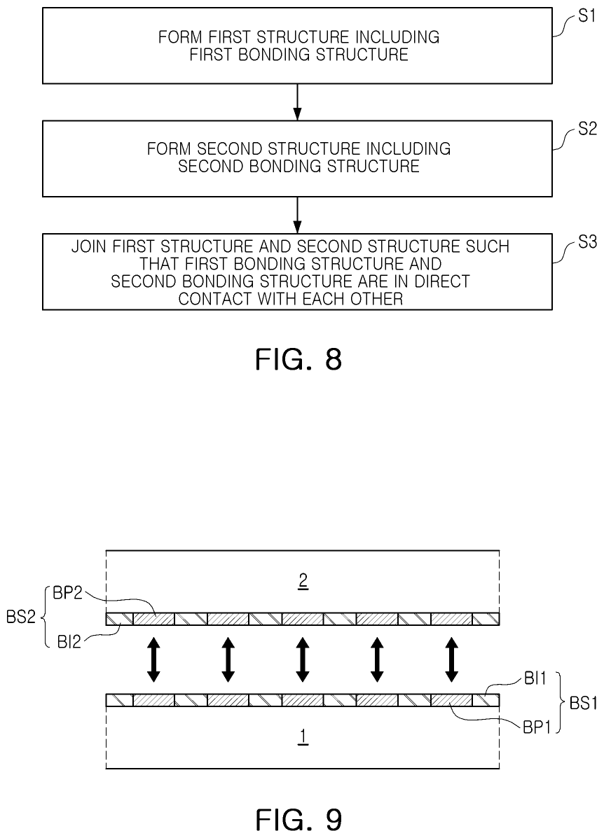

FIG. 8 is a flowchart illustrating a method of manufacturing a semiconductor package according to an embodiment according to a process sequence.

FIG. 9 illustrates a bonding process between a first structure 1 and a second structure 2, to illustrate a method of manufacturing a semiconductor package according to an embodiment.

In this specification, a first structure 1 and a second structure 2 may be referred to as a first semiconductor chip 100 and a second semiconductor chip 200, respectively, a first bonding pad BP1 and a second bonding pad BP2 may be referred to as a first pad 152 and a second pad 232, respectively, a first bonding insulating layer BI1 and a second bonding insulating layer BI2 may be referred to as a first insulating layer 151 and a second insulating layer 231, respectively.

Referring to FIGS. 8 and 9, a first structure 1 including a first bonding structure BS1 may be formed (51), a second structure 2 including a second bonding structure BS2 may be formed (S2), and the first structure 1 and the second structure 2 may be joined such that the first bonding structure BS1 and the second bonding structure BS2 are in direct contact with each other (S3).

The first bonding structure BS1 may include a first bonding pad BP1 and a first bonding insulating layer BI1 surrounding at least a portion of a side surface of the first bonding pad BP1, and the second bonding structure BS2 may include a second bonding pad BP2 and a second bonding insulating layer BI2 surrounding at least a portion of a side surface of the second bonding pad BP2. The first bonding pad BP1 and the second bonding pad BP2 may be in contact with each other, to be bonded by copper-to-copper bonding. Central axes of the first bonding pad BP1 and the second bonding pad BP2 may be shifted from each other for reasons of processing, but are not limited thereto. The first bonding insulating layer BI1 and the second bonding insulating layer BI2 may be in contact with each other, to be bonded by dielectric-to-dielectric bonding. The first bonding structure BS1 and the second bonding structure BS2 may be electrically connected to a redistribution layer or a through-via disposed on each of the first structure 1 and the second structure 2.

In an embodiment, joining of the first structure 1 and the second structure 2 may be die-to-die joining, die-to-wafer joining, or wafer-to-wafer joining. For example, when each of the first structure 1 and the second structure 2 is a semiconductor chip, joining of the first structure 1 and the second structure 2 may be die-to-die joining. For example, when the first structure 1 is one of a plurality of semiconductor structures divided into scribe lanes on a semiconductor wafer, and the second structure 2 is a semiconductor chip disposed on each of the plurality of semiconductor structures, joining of the first structure 1 and the second structure 2 may be die-to-wafer joining. For example, when the first structure 1 and the second structure 2 are one of a plurality of semiconductor structures divided into scribe lanes in each of the first semiconductor wafer and the second semiconductor wafer, joining of the first structure 1 and the second structure 2 may be wafer-to-wafer joining.

Hereinafter, a method for manufacturing the first structure 1 and the second structure 2 will be described.

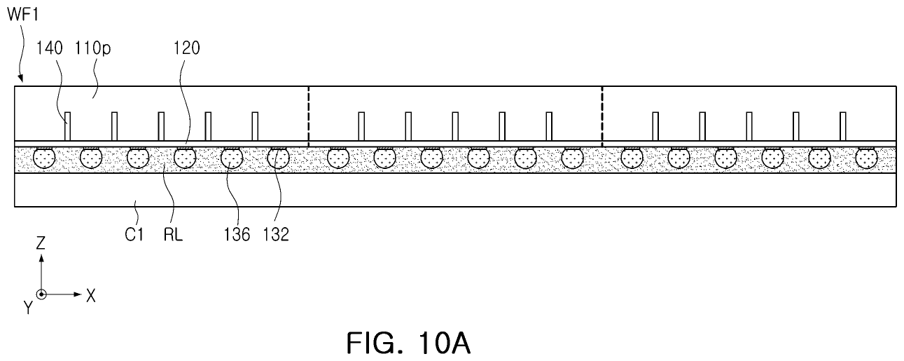

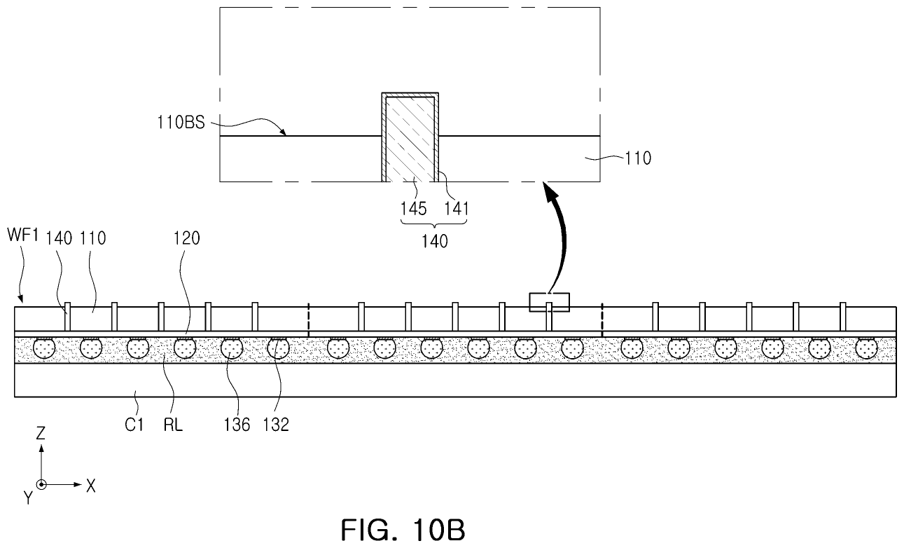

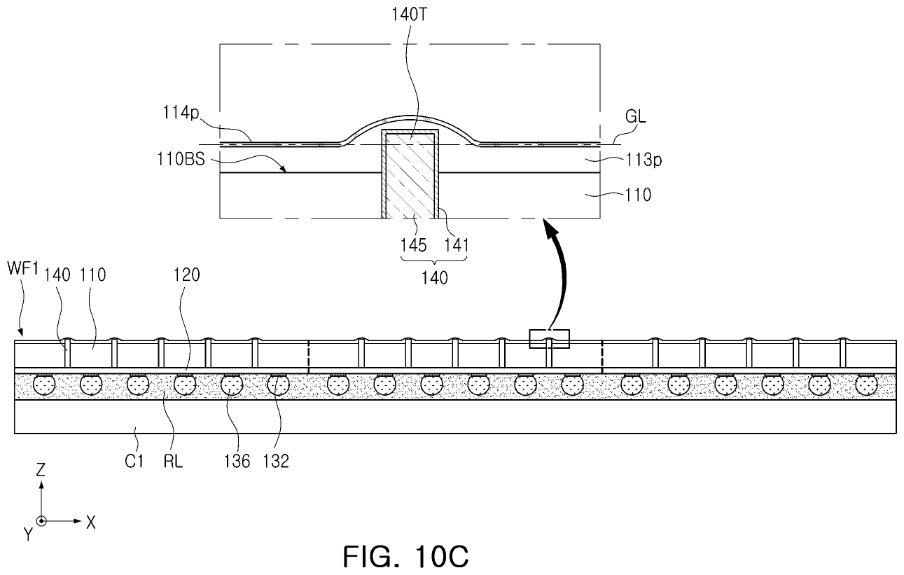

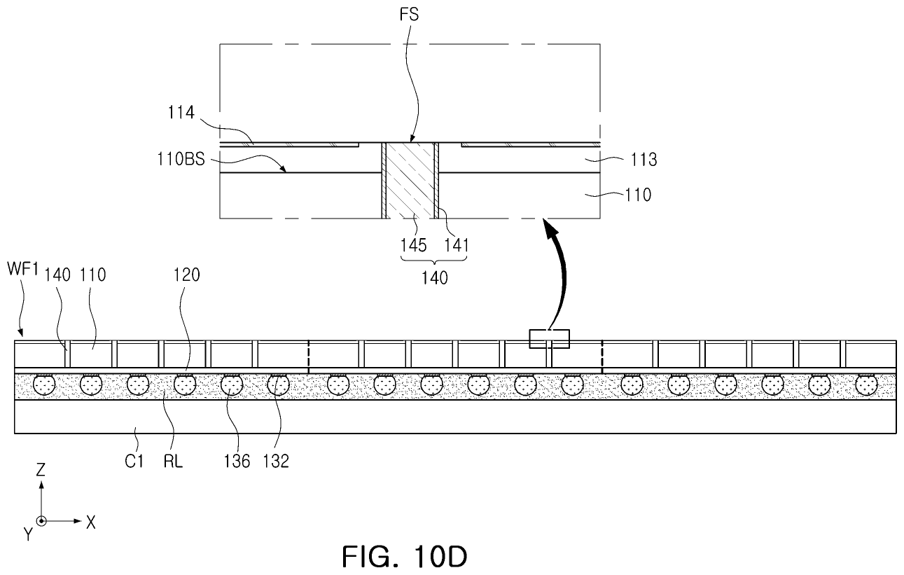

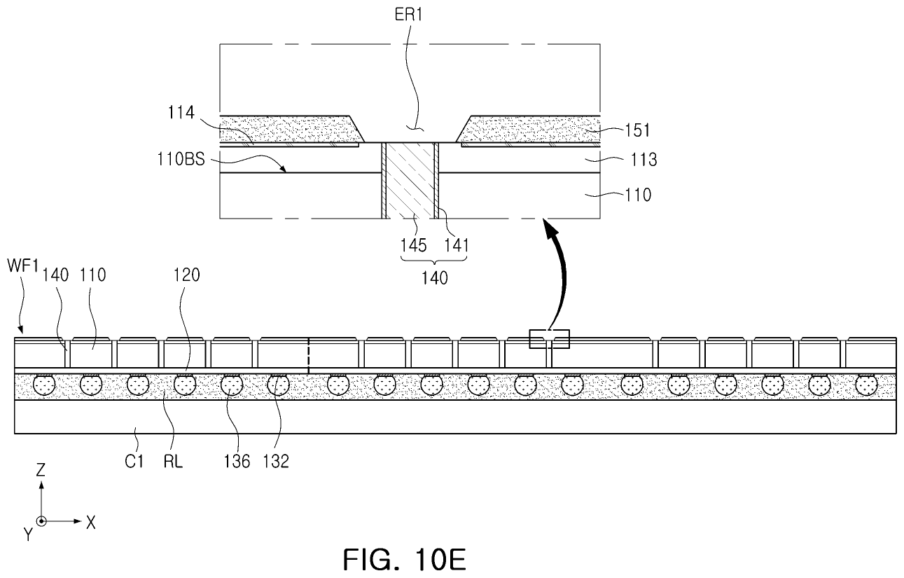

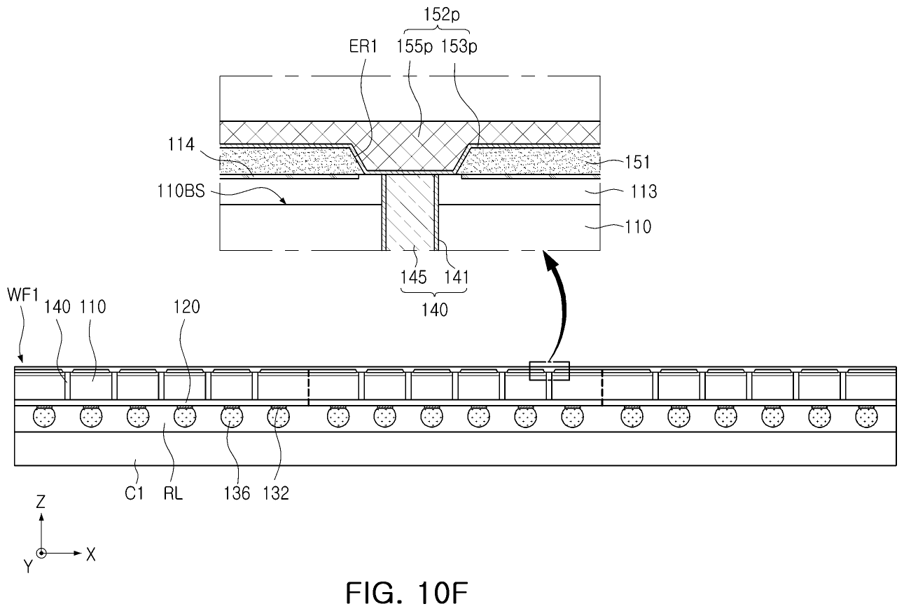

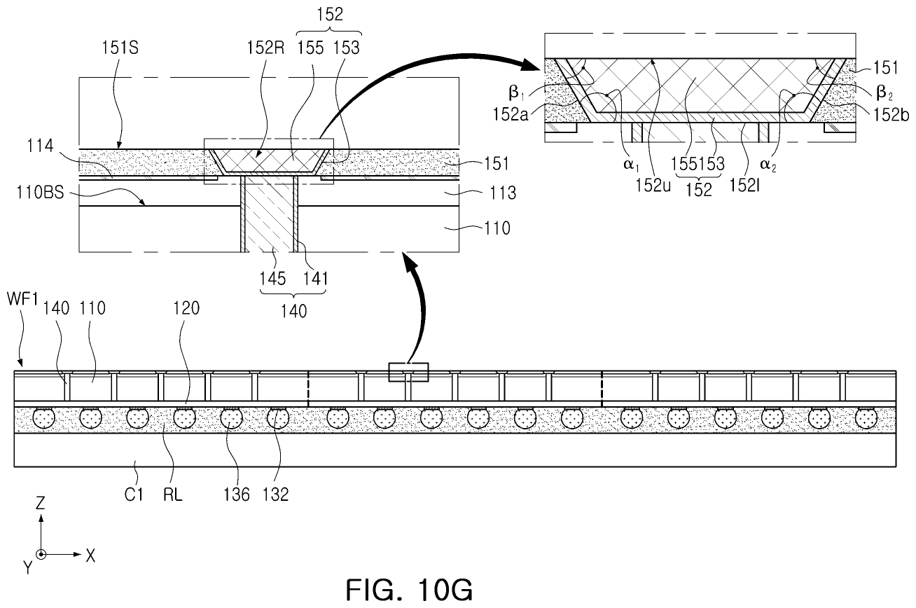

FIGS. 10A to 10G are cross-sectional views illustrating a manufacturing process for forming a first pad on a rear surface of a semiconductor chip. FIGS. 10A to 10G illustrate a portion of a manufacturing process of the first semiconductor chip 100 illustrated in FIG. 1A according to a process sequence.

Referring to FIG. 10A, a first semiconductor wafer WF1 including a first preliminary substrate 110p and a plurality of through-electrodes 140 arranged in the first preliminary substrate 110p may be prepared.

The first semiconductor wafer WF1 may be temporarily supported on a first carrier substrate C1 by a joining material layer RL such as glue. The first semiconductor wafer WF1 may include components for a plurality of semiconductor chips (or ‘first semiconductor chips’). Specifically, the first semiconductor wafer WF1 may include a first circuit layer 120 formed on an active surface of the first preliminary substrate 110p, and a plurality of through-electrodes 140 connected to the interconnection structure of the first circuit layer 120. The plurality of through-electrodes 140 may be formed before or during formation of the first circuit layer 120, not to completely penetrate the first preliminary substrate 110p. In addition, a connection bump 136 buried in the joining material layer RL may be disposed below the first semiconductor wafer WF1.

Referring to FIG. 10B, a portion of the first preliminary substrate 110p may be removed to form a first substrate 110 having a rear surface 110BS in or through which the plurality of through-electrodes 140 protrude.

The first substrate 110 having a desired thickness may be formed by applying a polishing process to an upper surface (an inactive surface) of the first preliminary substrate 110p. The polishing process may be performed by a grinding process such as a chemical mechanical polishing (CMP) process, an etch-back process, or a combination thereof. For example, the through-electrodes 140 may be sufficiently exposed by performing a grinding process to reduce the first preliminary substrate 110p to a certain thickness and applying an etch-back process under appropriate conditions.

Referring to FIG. 10C, a preliminary buffer film 114p and a preliminary protective layer 113p covering upper ends 140T of the through-electrodes 140 protruding onto or from the rear surface 110BS of the first substrate 110 may be formed. The preliminary protective layer 113p may be silicon oxide, and the preliminary buffer film 114p may be silicon nitride or silicon oxynitride. The preliminary protective layer 113p and the preliminary buffer film 114p may be formed using a PVD process or a CVD process. Subsequently, the preliminary protective layer 113p and the preliminary buffer film 114p may be planarized (e.g., ground) to expose the through-electrodes 140. Through the planarization process, the preliminary protective layer 113p and the preliminary buffer film 114p may be removed up to a predetermined line GL. In addition, portions of the upper ends 140T of the through-electrodes 140 may also be removed.

Referring to FIG. 10D, the first semiconductor wafer WF1 may have a flat surface FS from which a protective layer 113, a buffer film 114, and the plurality of through-electrodes 140 are exposed. As described above, since the upper ends 140T of the through-electrodes 140 may be partially removed by a planarization process, a portion of a via plug 145 may be exposed through the flat surface FS.

Referring to FIG. 10E, a rear insulating layer 151 including a first etch groove ER1 may be formed on a flat surface (‘FS’ in FIG. 10D) of the first semiconductor wafer WF1.

The first etch groove ER1 may be formed by etching at least a portion of a preliminary insulating layer formed on the protective layer 113 and the buffer film 114. The preliminary insulating layer may include, for example, silicon oxide (SiO) and/or silicon carbonitride (SiCN), and may be formed using a PVD or CVD process. The first etch groove ER1 may be formed using an etching process such as, for example, reactive-ion etching (RIE) or the like using a photoresist. In this case, the etching process may be performed to have side surfaces 152a and 152b inclined at first and second obtuse angles α1 and α2 with respect to a second surface 1521 of a rear pad 152, respectively (see FIG. 10G). Each of the first and second obtuse angles α1 and α2 may have magnitudes in a range of about 100° to about 130° or 100° to 130° (see FIG. 10G).

Referring to FIG. 10F, a preliminary rear pad 152p including a first preliminary barrier layer 153p and a first preliminary conductive layer 155p may be formed on a surface of the rear insulating layer 151 and inside the first etch groove ER1.

The first preliminary barrier layer 153p may be conformally formed along the surface of the rear insulating layer 151. The first preliminary conductive layer 155p may be formed on the first preliminary barrier layer 153p, and may fill an internal space of the first etch groove ER1. The first preliminary barrier layer 153p and the first preliminary conductive layer 155p may be formed using a plating process, a PVD process, or a CVD process. For example, the first preliminary barrier layer 153p may include titanium (Ti) or titanium nitride (TiN), and the first preliminary conductive layer 155p may include copper (Cu). A seed layer including the same material as the first preliminary conductive layer 155p may be formed between the first preliminary barrier layer 153p and the first preliminary conductive layer 155p.

Referring to FIG. 10G, a rear pad 152 including a first barrier layer 153 and a first conductive layer 155 may be formed by polishing the first preliminary barrier layer 153p and the first preliminary conductive layer 155p.

A portion of the first preliminary barrier layer 153p and a portion of the first preliminary conductive layer 155p may be removed by a polishing process, and a rear pad 152 including a first conductive layer 155 and a first barrier layer 153 may be formed. The polishing process may be performed using, for example, a CMP process using a first slurry. The first slurry may have polishing selectivity with respect to the first preliminary barrier layer 153p, the first preliminary conductive layer 155p, and the rear insulating layer 151.

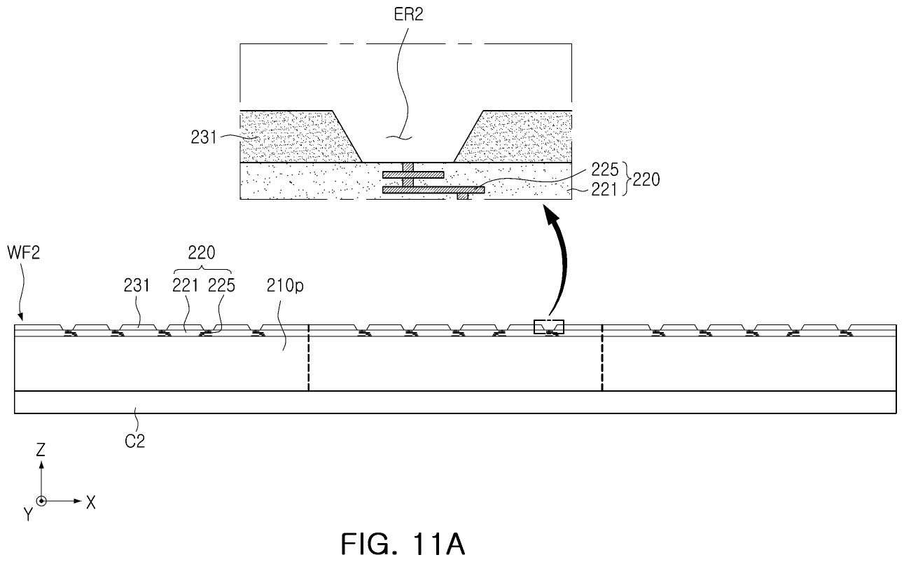

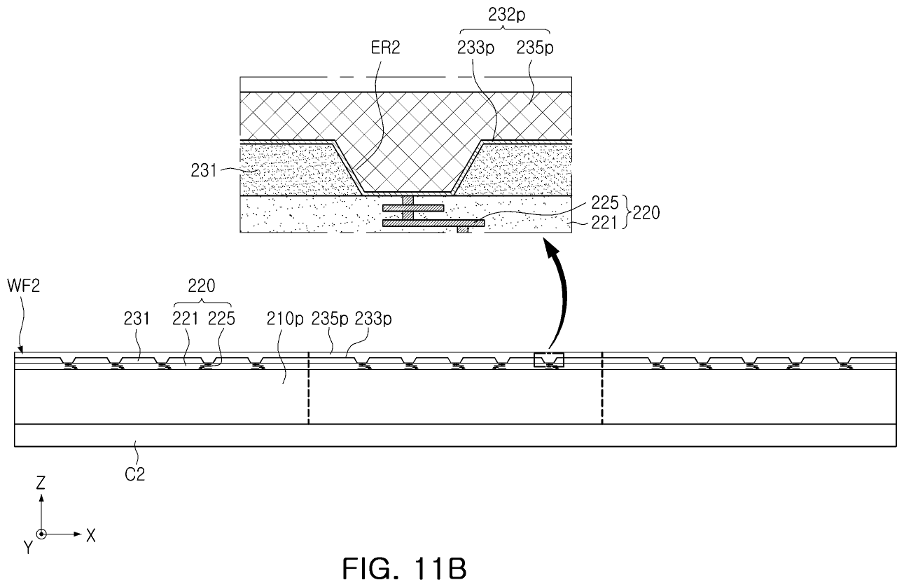

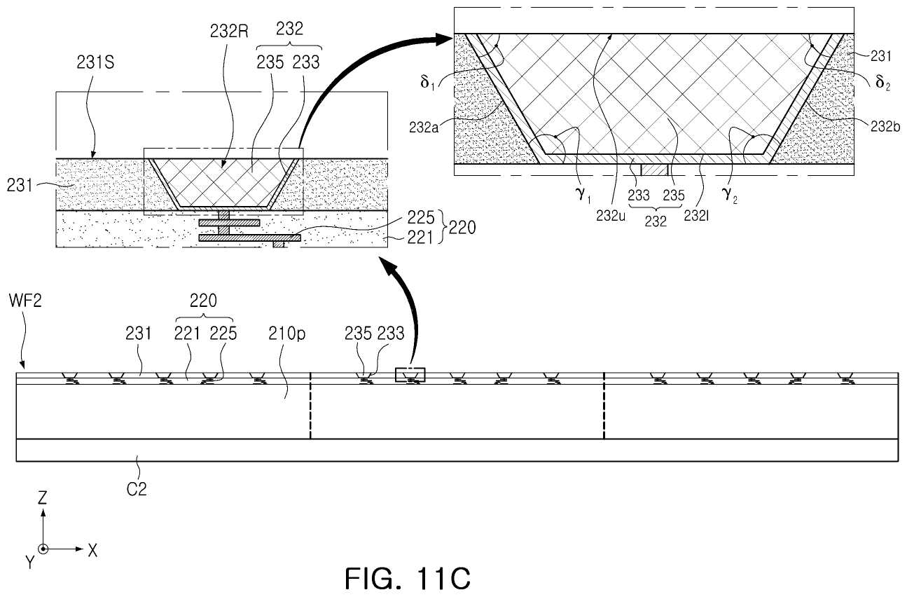

FIGS. 11A to 11C are cross-sectional views illustrating a manufacturing process for forming a second pad on a front surface of a semiconductor chip. FIGS. 11A to 11C illustrate a portion of a manufacturing process of the second semiconductor chip 200 illustrated in FIG. 1A according to a process sequence.

Referring to FIG. 11A, a front insulating layer 231 including a second etch groove ER2 may be formed on a second semiconductor wafer WF2.

The second semiconductor wafer WF2 may include a second preliminary substrate 210p, a second circuit layer 220 disposed on a front surface of the second preliminary substrate 210p, and a front insulating layer 231 disposed on the second circuit layer 220. The second semiconductor wafer WF2 may be supported and temporarily joined to a second carrier substrate C2. The second etch groove ER2 may be formed by etching at least a portion of a preliminary insulating layer formed on the second circuit layer 220. The preliminary insulating layer may include, for example, silicon oxide (SiO) and/or silicon carbonitride (SiCN), and may be formed using a PVD or CVD process. The second etch groove ER2 may be formed using an etching process such as, for example, reactive-ion etching (RIE) using a photoresist. In this case, the etching process may be performed to have a third side surface 232a inclined at a third obtuse angle γ1 with respect to a fourth surface 2321 of a front pad 232, and a fourth side surface 232b inclined at a fourth obtuse angle γ2 with respect to the fourth surface 2321 of the front pad 232 (see FIG. 11C). Each of the third obtuse angle γ1 and the fourth obtuse angle γ2 may range from about 100° to about 130° or 100° to 130° (see FIG. 11C).

Referring to FIG. 11B, a preliminary front pad 232p including a second preliminary barrier layer 233p and a second preliminary conductive layer 235p may be formed on a surface of the front insulating layer 231 and inside the second etch groove ER2.

The second preliminary barrier layer 233p may be conformally formed along the surface of the front insulating layer 231. The second preliminary conductive layer 235p may be formed on the second preliminary barrier layer 233p, and may fill an internal space of the second etch groove ER2. The second preliminary barrier layer 233p and the second preliminary conductive layer 235p may be formed using a plating process, a PVD process, or a CVD process. For example, the second preliminary barrier layer 233p may include titanium (Ti) or titanium nitride (TiN), and the second preliminary conductive layer 235p may include copper (Cu). A seed layer including the same material as the second preliminary conductive layer 235p may be formed between the second preliminary barrier layer 233p and the second preliminary conductive layer 235p.

Referring to FIG. 11C, a front pad 232 including a second barrier layer 233 and a second conductive layer 235 may be formed by polishing the second preliminary barrier layer 233p and the second preliminary conductive layer 235p.

A portion of the second preliminary conductive layer 235p and a portion of the second preliminary barrier layer 233p may be removed by a polishing process, and a front pad 232 including a second conductive layer 235 and a second barrier layer 233 may be formed. The polishing process may be performed using, for example, a CMP process using a first slurry. The first slurry may have polishing selectivity with respect to the second preliminary barrier layer 233p, the second preliminary conductive layer 235p, and the front insulating layer 231. Thereafter, a rear surface of the second preliminary substrate 210p may be ground to form a plurality of semiconductor chips 200 (or ‘second semiconductor chips’) having a desired thickness.

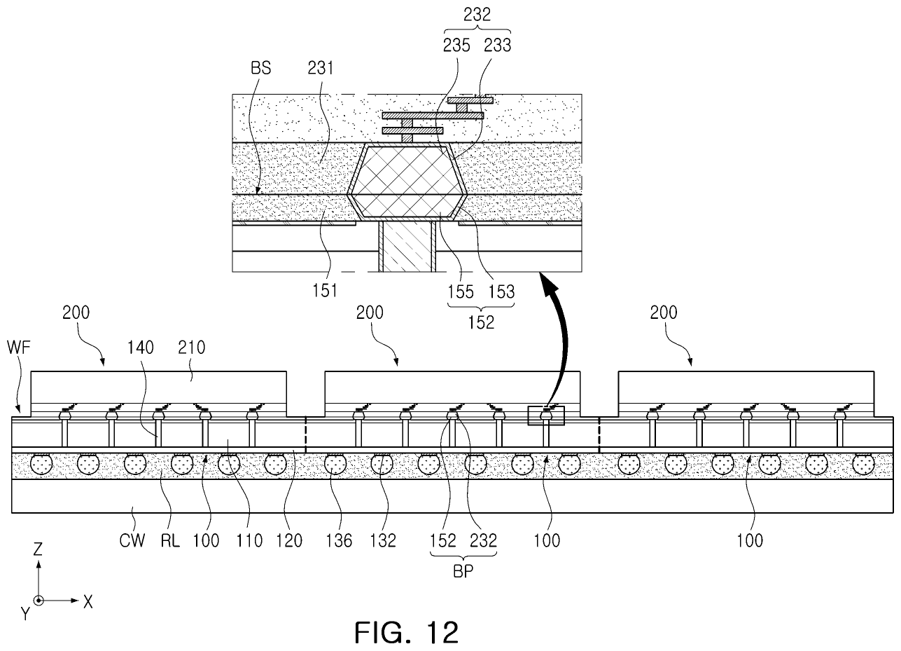

FIG. 12 is a cross-sectional view illustrating a manufacturing process of the semiconductor package 10 of FIG. 1A.

Referring to FIG. 12, first, a semiconductor wafer WF provided for first semiconductor chips 100 may be prepared. The semiconductor wafer WF may be formed by the manufacturing processes of FIGS. 10A to 10G. The semiconductor wafer WF may include a plurality of rear pads 152 and a rear insulating layer 151 surrounding the plurality of rear pads 152. The semiconductor wafer WF may be supported on a temporary carrier CW by a joining material layer RL.

Next, a plurality of second semiconductor chips 200 may be prepared. The plurality of second semiconductor chips 200 may be formed by the manufacturing processes of FIGS. 11A to 11C. The plurality of second semiconductor chips 200 may include a plurality of front pads 232 and a front insulating layer 231 surrounding the plurality of front pads 232. The semiconductor wafer WF and the plurality of second semiconductor chips 200 may not be sequentially prepared, and may be formed by independent manufacturing processes.

Next, the plurality of second semiconductor chips 200 may be disposed on the semiconductor wafer WF. The plurality of second semiconductor chips 200 may be disposed on the first semiconductor chips 100 of the semiconductor wafer WF by using, for example, a pick-and-place device. The plurality of second semiconductor chips 200 may be aligned with the first semiconductor chips 100. Therefore, the plurality of rear pads 232 may be in contact with the plurality of front pads 152, and the rear insulating layer 151 may be in contact with the front insulating layer 231.

Next, a thermal compression process may be performed to bond the rear insulating layer 151 and the front insulating layer 231 joined to each other, and to bond the plurality of rear pads 152 and the plurality of front pads 232 joined to each other. The thermal compression process may be performed such that the rear insulating layer 151 and the front insulating layer 231 may be first bonded, and then the plurality of rear pads 152 and the plurality of front pads 232 may be bonded. For example, the thermal compression process may be performed such that the rear insulating layer 151 and the front insulating layer 231 are bonded under a thermal atmosphere ranging from about 100° C. to about 200° C., and the plurality of rear pads 152 and the plurality of front pads 232 are bonded under a thermal atmosphere ranging from about 200° C. to about 300° C. A temperature of the thermal atmosphere is not limited to the above-described range (about 100° C. to about 300° C.), and may be variously changed.

According to embodiments, a lower surface and a side surface of the first pad may be introduced to have a certain angle, to provide a semiconductor package preventing defects during pad formation and having improved reliability.

While example embodiments have been illustrated and described above, it will be apparent to those skilled in the art that modifications and variations could be made without departing from the scope of the present disclosure as defined by the appended claims.

What is claimed is:

1. A semiconductor package comprising:
a first semiconductor chip including a first substrate, a first pad on the first substrate, and a first insulating layer at least partially surrounding the first pad on the first substrate; and
a second semiconductor chip on the first semiconductor chip, and including a second substrate, a second pad below the second substrate and contacting the first pad, and a second insulating layer at least partially surrounding the second pad and contacting the first insulating layer,
wherein the first pad includes a first surface contacting the second pad and a second surface opposite the first surface, and an inclined side surface between the first surface and the second surface,
wherein the inclined side surface includes a first side surface and a second side surface, facing each other and inclined at a first obtuse angle and a second obtuse angle with respect to the second surface, respectively, and
wherein each of the first and second obtuse angles is about 100° to about 130°.

2. The semiconductor package of claim 1, wherein the second pad comprises:
a third surface contacting the first pad;
a fourth surface opposite the third surface; and
an inclined side surface between the third surface and the fourth surface,
wherein the inclined side surface includes a third side surface and a fourth side surface, facing each other and inclined at a third obtuse angle and a fourth obtuse angle with respect to the fourth surface, respectively, and
each of the third and fourth obtuse angles are about 100° to about 130°.

3. The semiconductor package of claim 1, wherein the first and second obtuse angles are different from each other.

4. The semiconductor package of claim 2, wherein the third and fourth obtuse angles are different from each other.

5. The semiconductor package of claim 1, wherein a thickness of the first pad is less than a thickness of the second pad.

6. The semiconductor package of claim 1, wherein a thickness of the first pad is substantially equal to a thickness of the second pad.

7. The semiconductor package of claim 1, wherein the first pad and the second pad are symmetrical with respect to a surface on which the first pad and the second pad are in contact with each other.

8. The semiconductor package of claim 1, wherein the second insulating layer comprises a lower insulating film directly contacting the first insulating layer and an upper insulating film on the lower insulating film, and
wherein the lower insulating film includes an insulating material, different from an insulating material of the first insulating layer.

9. The semiconductor package of claim 8, wherein the first insulating layer includes silicon oxide (SiO), and
wherein the lower insulating film of the second insulating layer includes silicon carbon nitride (SiCN).

10. The semiconductor package of claim 1, wherein the second semiconductor chip comprises a plurality of second semiconductor chips stacked on the first semiconductor chip in a vertical direction, and
wherein each of the plurality of second semiconductor chips includes a rear insulating layer and a front insulating layer.

11. The semiconductor package of claim 1, wherein the first pad comprises a first conductive layer and a first barrier layer surrounding a side surface of the first conductive layer, and
wherein the second pad comprises a second conductive layer contacting at least a portion of the first conductive layer, and a second barrier layer surrounding a side surface of the second conductive layer.

12. The semiconductor package of claim 11, wherein the first conductive layer includes a first groove exposing at least a portion of the first barrier layer, and
the second conductive layer includes a second groove exposing at least a portion of the second barrier layer.

13. The semiconductor package of claim 1, wherein the first semiconductor chip further comprises a first circuit layer below the first substrate, a lower pad below the first circuit layer, and a first through-electrode extending through the first substrate and electrically connecting the first pad and the lower pad.

14. A semiconductor package comprising:
a first semiconductor chip including a first substrate, a first pad on the first substrate, and a first insulating layer at least partially surrounding the first pad on the first substrate; and
a second semiconductor chip on the first semiconductor chip, and including a second substrate, a second pad below the second substrate and contacting the first pad, and a second insulating layer at least partially surrounding the second pad and contacting the first insulating layer,
wherein the first pad includes a first surface contacting the second pad, a second surface opposite the first surface, and a first side surface between the first surface and the second surface and inclined with respect to the second surface at a first obtuse angle, and
the second pad includes a third surface contacting the first pad, a fourth surface opposite the third surface, and a second side surface between the third surface and the fourth surface and inclined with respect to the fourth surface at a second obtuse angle,
wherein each of the first and second obtuse angles is about 100° to about 130°.

15. The semiconductor package of claim 14, wherein the first pad has a trapezoidal shape.

16. The semiconductor package of claim 14, wherein the first obtuse angle and the second obtuse angle are different from each other.

17. The semiconductor package of claim 14, wherein the first semiconductor chip further comprises a first circuit layer below the first substrate, a lower pad below the first circuit layer, and a first through-electrode extending through the first substrate and electrically connecting the first pad and the lower pad.

18. A semiconductor package comprising:
a first semiconductor chip including a first substrate, a first pad on the first substrate, a first insulating layer at least partially surrounding the first pad on the first substrate, an insulating protective layer between the first substrate and the first insulating layer, a through-electrode extending through the first substrate and the insulating protective layer and connected to the first pad, and a buffer film on the insulating protective layer and spaced apart from the through-electrode; and
a second semiconductor chip on the first semiconductor chip, and including a second substrate, a second pad below the second substrate and contacting the first pad, and a second insulating layer at least partially surrounding the second pad and contacting the first insulating layer,
wherein the first pad includes a first surface contacting the second pad and a second surface opposite the first surface; and an inclined side surface between the first surface and the second surface,
wherein the first pad has a first side surface and an opposite second side surface inclined at a first obtuse angle and a second obtuse angle with respect to the second surface, respectively, and
wherein each of the first and second obtuse angles is about 100° to about 130°.

19. The semiconductor package of claim 18, wherein the buffer film is spaced apart from the first pad.

20. The semiconductor package of claim 18, wherein a thickness of the first pad is substantially equal to a thickness of the second pad.
